(19) United States
(12) Patent Application Publication
(10) Pub. No.: US 2009/0066349 A1
(43) Pub. Date: Mar. 12, 2009

(54) PROBE SYSTEM

(75) Inventors: Fan-Hsien Hsu, Hsinchu County (TW); Kuang-Hsuan Chiu, Miaoli County (TW); Li-Tien Yang, Hsinchu City (TW); Yu-Hsin Liu, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: POWERCHIP SEMICONDUCTOR CORP., Hsinchu (TW)

(21) Appl. No.: 12/022,164

(22) Filed: Jan. 30, 2008

(30) Foreign Application Priority Data
Sep. 6, 2007 (TW) 96133212

(51) Int. Cl. G01R 1/06

(52) U.S. Cl. 324/754

(57) ABSTRACT

A probe system including a body, a testing apparatus, a probe card, and a strengthening mechanism is provided. The testing apparatus is disposed above the body. The probe card is disposed between the testing apparatus and the body. The strengthening mechanism is disposed between the probe card and the testing apparatus to have the probe card leaned against it. The strengthening mechanism has at least one elastic element.

### CROSS-REFERENCE TO RELATED APPLICATION

This application claims the priority benefit of Taiwan application serial no. 96133212, filed on Sep. 6, 2007. The entirety of the above-mentioned patent application is hereby incorporated by reference herein and made a part of this specification.

### BACKGROUND OF THE INVENTION

1. Field of the Invention

The present invention relates to a test system of a semiconductor device. More particularly, the present invention relates to a probe system.

2. Description of Related Art

Generally speaking, in order to ensure a reliability of products, a semiconductor package test is mainly divided into two parts including a wafer probe and sort after a wafer processing is completed and a final test after packaging. In order to ensure the yield of the wafer and meanwhile avoid any waste in packaging, a electrical property and function test must be first carried out the wafer after being fabricated and before diced and packaged, so as to determine whether the wafer process is normal or not.

When performing the wafer probe and sort, a probe pin of a probe card is used to directly contact a pad or a bump on a testing chip, so as to perform the test. Next, a chip signal data after every chip on the wafer is detected is sent to a testing apparatus for further analysis and determination. Then, the defective devices will be replaced according to the data. Therefore, before packaging, the chips with poor electrical properties and functions may be removed, thus improving the yield and lowering the manufacturing cost.

However, when the probe contacts the chip, different sized probe marks may be generated under different probe pressures. That is, if a probe pressure is very high, the probe will leave a large-area probe mark on the pad or the bump. If the probe pressure is very low, the probe will leave a small-area probe mark on the pad or the bump. Different sized probe marks generated by the probe will lead to different test results, thus influencing the measurement result of the electrical properties of the chips.

FIG. 1 is a schematic view of an actuation of a conventional wafer probe and sort.

As shown in FIG. 1, when performing the wafer probe and sort, a chuck 102 for carrying a testing wafer 104 is capable of moving upwardly to make the testing wafer 104 directly contact a probe card 100. With the progress of the semiconductor process, the size of the testing wafer 104 is enlarged, and the area of the probe card 100 for testing is also expanded. However, as the area of the probe card 100 is expanded, a contact force F generated when the probe card 100 contacts the testing wafer 104 may deform the probe card 100. The above deformation occurs since the structural strength in the central area of the probe card 100 is insufficient to withstand a reaction force caused by the contact force F, such that the probe card 100 is bent and deformed in the stress direction. If the bent probe card 100 proceeds to carry out the wafer probe and sort, the central bent portion are prone to generate a very small probe mark, thus influencing the test results.

Therefore, directed to the above problem, it is a challenge in this industry to eliminate the problem of the deformation of the probe card so as to obtain consistent probe marks.

### SUMMARY OF THE INVENTION

The present invention is directed to a probe system, which is capable of withstanding the reaction force caused by a contact force, so as to prevent bending of the probe card.

The present invention provides a probe system, which includes a body, a testing apparatus, a probe card, and a strengthening mechanism. The testing apparatus is disposed above the body. The probe card is disposed between the testing apparatus and the body. The strengthening mechanism is disposed between the probe card and the testing apparatus to have the probe card leaned against it. The strengthening mechanism has at least one elastic element.

In an embodiment of the present invention, the strengthening mechanism further includes an upper panel and a lower panel, and the lower panel is fixed below the upper panel at a distance.

In an embodiment of the present invention, the elastic element is, for example, disposed between the upper panel and the lower panel.

In an embodiment of the present invention, the size of the upper panel is, for example, greater than that of the lower panel.

In an embodiment of the present invention, a material of the upper and the lower panels is, for example, steel.

In an embodiment of the present invention, a shape of the upper and lower panels is, for example, round.

In an embodiment of the present invention, the elastic element is, for example, a compression spring.

In an embodiment of the present invention, the elastic element is, for example, disposed corresponding to a center point of the strengthening mechanism.

In an embodiment of the present invention, when a plurality of elastic elements is used, the elastic elements are radially disposed symmetrically about the center point of the strengthening mechanism.

In an embodiment of the present invention, the testing apparatus includes a test head and a mother board, and the test head is, for example, disposed above the mother board.

In an embodiment of the present invention, the strengthening mechanism is, for example, fixed below the mother board.

In an embodiment of the present invention, the probe system further includes a fixing unit, for fixing the probe card to the body.

In an embodiment of the present invention, the probe system further includes a chuck disposed in the body, for carrying a testing wafer.

In view of the above, the present invention adopts a strengthening mechanism having an elastic element disposed between the probe card and the testing apparatus. Thus, when the probe card contacts the wafer, the probe card can withstand the reaction force of a contact force through the strengthening mechanism, thus preventing bending.

Further, the present invention improves the consistency of the probe marks by simply disposing a strengthening mechanism, instead of re-designing the material, shape, and size of the probe card, thereby lowering the testing cost.

In order to make the aforementioned and other objectives, features, and advantages of the present invention comprehensible, embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of an actuation of a conventional wafer probe and sort.

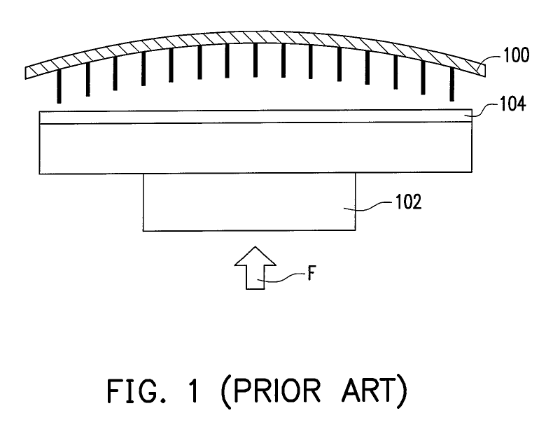

FIG. 2 is a schematic cross-sectional view of a probe system according to an embodiment of the present invention.

FIG. 3 is a schematic bottom view of a strengthening mechanism according to an embodiment of the present invention.

### DESCRIPTION OF EMBODIMENTS

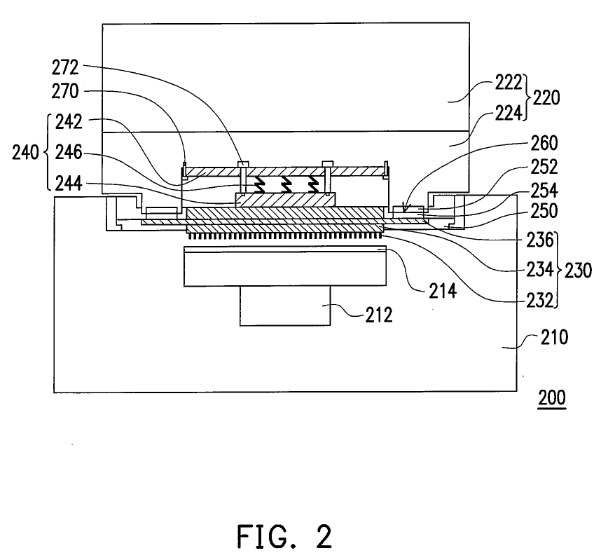

FIG. 2 is a schematic cross-sectional view of a probe system according to an embodiment of the present invention.

Referring to FIG. 2, the probe system 200 includes a body 210, a testing apparatus 220, a probe card 230, and a strengthening mechanism 240. The testing apparatus 220 is, for example, disposed above the body 210. The probe card 230 is, for example, disposed between the testing apparatus 220 and the body 210. The strengthening mechanism 240 is, for example, disposed between the probe card 230 and the testing apparatus 220.

The body 210 has a chuck 212, for carrying a testing wafer 214. The chuck 212 is, for example, a lifting apparatus, which moves up and down to make the testing wafer 214 disposed thereon to directly contact the probe card 230.

The testing apparatus 220 includes a test head 222 and a mother board 224. The test head 222 is, for example, connected above the mother board 224. Further, the other end of the test head 222 is, for example, connected to a control system (not shown), such that the operations such as actuation and measurement of the testing apparatus 220 may be manipulated via the control system.

The probe card 230 includes probe pins 232, a metal layer 234, and a circuit substrate 236. The material of the metal layer 234 is, for example, an alloy. The circuit substrate 236 is, for example, a printed circuit board (PCB). One end of the probe pins 232, for example, face the testing wafer 214, and the other end of the probe pins 232 is, for example, connected to the metal layer 234. The probe pins 232 and the metal layer 234 are fixed onto the circuit substrate 236 by, for example, soldering. Each probe pin 232 is, for example, electrically coupled to a corresponding circuit on the circuit substrate 236.

Accordingly, the probe card 230 is, for example, fixed onto the body 210 through a retainer 250. Elastic pins 252 below the testing apparatus 220, for example, directly contact elastic connectors 254 of the probe card 230, so as to form an electrical conduction across an interface 260 between the mother board 224 and the circuit substrate 236. It should be noted that the probe card 230 can receive a test signal from the testing apparatus 220 through the interface 260 to perform the wafer probe and sort, and transmit the test signal to the testing wafer 214 through the probe pins 232 disposed on the probe card 230, thereby determining whether the electrical properties and functions of the device is normal or not.

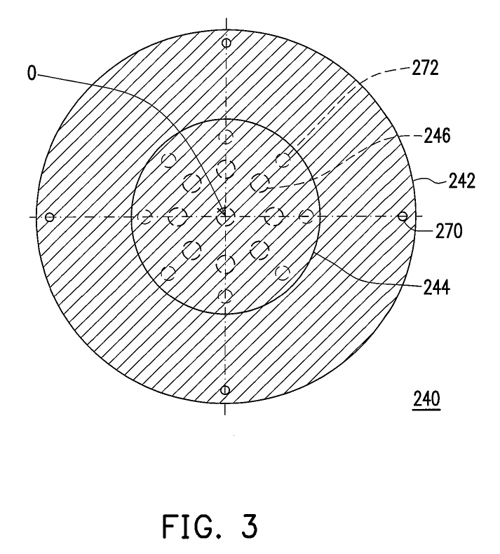

FIG. 3 is a schematic bottom view of a strengthening mechanism according to an embodiment of the present invention.

Referring to FIGS. 2 and 3 together, the strengthening mechanism 240, for example, includes an upper panel 242, a lower panel 244, and at least one elastic element 246. The material of the upper panel 242 and the lower panel 244 is, for example, steel. In this embodiment, the shape of the upper panel 242 and the lower panel 244 is round, and the size of the upper panel 242 is greater than that of the lower panel 244. The upper panel 242 is, for example, fixed below the mother board 224 through bolts 270. The upper panel 242 and the lower panel 244 are, for example, the corresponding to the same center of a circle O and adjacent to each other on a vertical plane. The lower panel 244 is, for example, fixed below the upper panel 242 at a fixed distance through shoulder screws 272. The lower surface of the lower panel 244 is, for example, attached on the metal layer 234, so as to make the probe card 230 leaned against the strengthening mechanism 240. The elastic element 246 is disposed between the upper panel 242 and the lower panel 244. The elastic element 246 is, for example, a compression spring.

As shown in FIG. 3, in this embodiment, when a plurality of elastic elements 246 is disposed between the upper panel 242 and the lower panel 244, the elastic elements 246 are radially scattered between the upper panel 242 and the lower panel 244 and symmetric about the center point O of a circle. It should be noted that since the elastic elements 246 and the upper and lower panels 242, 244 are concentrically disposed, the elastic elements 246 facilitate the lower panel 244 exerting a force uniformly on the probe card 230, so as to withstand the reaction force caused by a contact force. Further, a plurality of shoulder screws 272 is disposed surrounding the elastic elements 246, so as to fix the periphery of the lower panel 244 below the upper panel 242, such that the elastic elements 246 are stably fixed between the upper panel 242 and the lower panel 244.

Definitely, the type and number of the disposed elastic elements 246 are not limited to the above embodiment. Those skilled in the art can determine the type and number of the disposed elastic elements 246 according to a contact force calculated based on various characteristics of the probe pins 232 of the probe card 230. Moreover, a strengthening mechanism 240 having a plurality of elastic elements 246 is described for illustration, but the present invention is not limited thereto. In other embodiments, the strengthening mechanism 240 may have more than one elastic element 246. The arrangement of the elastic elements 246 is not limited to the above embodiment, as long as the elastic elements 246 are disposed symmetrically about the center point O of a circle to realize the uniform application of force. Further, the vertical distance between the upper panel 242 and the lower panel 244 may be adjusted according to the type of the probe card 230, which is not particularly restricted in the present invention.

It should be noted that, when the chuck 212 moves upward to make the testing wafer 214 disposed thereon to contact the probe pins 232 of the probe card 230, since the strengthening mechanism 240 has the elastic elements 246, the reaction force caused by a contact force may be absorbed by the strengthening mechanism 240 disposed above the probe card 230. Therefore, the probe card 230 can withstand the reaction force caused by a contact force through the strengthening mechanism 240, so as to prevent bending of the central area of the probe card 230.

In view of the above, the present invention adopts a strengthening mechanism disposed between the probe card and the testing apparatus. The strengthening mechanism has the elastic element for applying force uniformly on the probe card. When the probe card contacts the wafer, the strengthening mechanism can withstand the reaction force caused by a contact force, and thus the problem that a bent probe card may generate a very small probe mark can be avoided.

Further, the present invention solves the problem of the bending of the probe card without changing the material, shape, and size of the probe card, and meanwhile obtains consistent probe marks. Therefore, the cost of the wafer probe and sort is lowered.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A probe system, comprising:
a body;
a testing apparatus, disposed above the body;
a probe card, disposed between the testing apparatus and the body; and
a strengthening mechanism, disposed between the probe card and the testing apparatus, so as to have the probe card leaned against it, wherein the strengthening mechanism comprises at least one elastic element.

2. The probe system as claimed in claim 1, wherein the strengthening mechanism further comprises an upper panel and a lower panel, and the lower panel is fixed below the upper panel at a distance.

3. The probe system as claimed in claim 2, wherein the elastic element is disposed between the upper panel and the lower panel.

4. The probe system as claimed in claim 2, wherein a size of the upper panel is greater than that of the lower panel.

5. The probe system as claimed in claim 2, wherein a material of the upper and the lower panels is steel.

6. The probe system as claimed in claim 2, wherein a shape of the upper and the lower panels is round.

7. The probe system as claimed in claim 1, wherein the elastic element comprises compression spring.

8. The probe system as claimed in claim 1, wherein the elastic element is disposed corresponding to a center point of the strengthening mechanism.

9. The probe system as claimed in claim 8, wherein when a plurality of elastic elements exists, the elastic elements are disposed symmetrically about the center point of the strengthening mechanism in a radial manner.

10. The probe system as claimed in claim 1, wherein the testing apparatus comprises a test head and a mother board, and the test head is disposed above the mother board.

11. The probe system as claimed in claim 10, wherein the strengthening mechanism is fixed below the mother board.

12. The probe system as claimed in claim 1, further comprising a fixing unit, for fixing the probe card to the body.

13. The probe system as claimed in claim 1, further comprising a chuck, disposed in the body, for carrying a testing wafer.
